(19) United States
(12) Patent Application Publication
(10) Pub. No.: US 2024/0145574 A1
(43) Pub. Date: May 2, 2024

(54) MANUFACTURING METHOD OF CIRCUITRY INCLUDING PLANAR DIODE

(71) Applicants: The University of Electro-Communications, Tokyo (JP); Space Power Technologies Inc., Kyoto (JP)

(72) Inventors: Shinji NOZAKI, Tokyo (JP); Kazuo UCHIDA, Tokyo (JP); Minoru FURUKAWA, Kyoto (JP); Yuji TAKEDA, Kyoto (JP)

(21) Appl. No.: 18/279,706

(22) PCT Filed: Mar. 9, 2022
(86) PCT No.: PCT/JP2022/010382

§ 371 Date: Aug. 31, 2023

(30) Foreign Application Priority Data
Mar. 11, 2021 (JP) 2021-038902

(51) Int. Cl. H01L 29/66

(52) U.S. Cl. CPC H01L 29/66128; H01L 29/66143

(57) ABSTRACT

A manufacturing method of a circuitry including a planar diode that can improve manufacturing precision of a connection between the planar diode and a circuit element connected to an electrode of the planar diode is provided. The manufacturing method of the circuitry including the planar diode includes: forming an insulating layer having a first pattern shape on a substrate; and monolithically forming a functional material layer having a second pattern shape complementary to the first pattern shape on the substrate. The functional material layer includes a material that functions as a planar diode having a rectifying property based on a shape and a size. The second pattern shape has a shape of a circuitry including the planar diode, a first circuit element connected to a first electrode of the planar diode, and a second circuit element connected to a second electrode of the planar diode.

### TECHNICAL FIELD

The present invention relates to a manufacturing method of a circuitry including a planar diode.

### BACKGROUND

There is a method to generate electricity by using a rectenna. A rectenna is provided with an antenna and a diode, and can rectify electromagnetic waves into direct current to convert into electrical energy. In particular, an optical rectenna that converts light of all spectrums, such as infrared rays, visible rays, and ultraviolet rays that derive from the sun and the like, into electrical energy has attracted attention. However, as antennas corresponding to these wavelengths of light are minute, high precision is required to manufacturing method thereof.

In relation to the above, Patent Literature 1 (Japanese Patent No. 5607676) discloses an invention of a rectifying device. This rectifying device is provided with a first electrode, a second electrode, and a semiconductor layer. The first electrode has a first work function. The second electrode has a second work function greater than the first work function. The semiconductor layer has a third work function with a value between the first work function and the second work function, and is bonded to the first electrode and the second electrode. The semiconductor layer is made of NiOx (x=1 to 1.5) with holes as carriers, which is produced by oxidizing Ni by irradiating it with ultraviolet rays, is set to a thickness to become completely depleted in a state where no bias voltage is applied between the first electrode and the second electrode, and functions as a fully depleted Schottky diode.

The rectenna according to the Patent Literature 1 has two metallic elements arranged on a same substrate. These two metallic elements are manufactured in two manufacturing processes, respectively. An intersectional portion of these two metallic elements functions as a diode. In addition, each end portion of the two metallic elements functions as an antenna. However, when the two manufacturing processes are misaligned and the two end portions are not aligned, these two end portions do not function as an antenna, and therefore the rectenna does not function.

In addition, a Non-Patent Literature 1 (Shun So, Department of Advanced Engineering Physics, 2017, University of Electro-communications, Master's thesis) discloses a planar rectenna. This planar rectenna has two metallic elements and a diode that are arranged on a same substrate. As this diode, a planar diode made of nickel oxide is employed.

As the two metallic elements in the rectenna according to the Non-Patent Literature 1 are made in a single manufacturing process, it is considered that a manufacturing process of arranging the end portion of each metallic element on a straight line has a sufficient precision. On the other hand, the diode is made in a manufacturing process different from the one of these two metallic elements. When the two manufacturing methods are misaligned and there is a defection in a bonding between the two metallic elements and the diode, the rectenna does not function.

### CITED REFERENCE

### Patent Literature

[Patent Literature 1] Japanese Patent No. 5607676

### Non-Patent Literature

[Non-Patent Literature 1] Shun So, Department of Advanced Engineering Physics, 2017, University of Electro-communications, Master's thesis.

### SUMMARY

A manufacturing method of a circuitry including a planar diode that can improve manufacturing precision of a connection between the planar diode and a circuit element connected to an electrode of the planar diode is provided. Other problems to be solved and novel features will become apparent from the disclosure of the present description and attached drawings.

According to an embodiment, a manufacturing method of a circuitry including a planar diode includes forming an insulation layer having a first pattern shape on a substrate and monolithically forming a functional material layer having a second pattern shape complementary to the first pattern shape on the substrate. The functional material layer includes a material that functions as a planar diode having a rectifying property based on a shape and a size. The second pattern shape has a shape of a circuitry including the planar diode, a first circuit element connected to a first electrode of the planar diode, and a second circuit element connected to a second electrode of the planar diode.

According to the embodiment, a manufacturing precision of a connection between a planar diode and a circuit element connected to an electrode of the planar diode can be improved.

### BRIEF DESCRIPTION OF THE DRAWINGS

FIG. 1 is a plan view showing a configuration example of a rectenna according to a first related art.

FIG. 2 is a plan view showing another configuration example of a rectenna according to the first related art.

FIG. 3A is a plan view showing a configuration example of a rectenna according to second related art.

FIG. 3B is a cross-sectional view by a cross-sectional line A-A of the rectenna shown in FIG. 3A.

FIG. 4 is a plan view showing another configuration example of the rectenna according to the second related art.

FIG. 5A is a plan view showing a configuration example of a rectenna according to an embodiment.

FIG. 5B is a cross-sectional view by a cross-sectional line B-B of the rectenna shown in FIG. 5A.

FIG. 5C is a cross-sectional view by a cross-sectional line C-C of the rectenna shown in FIG. 5A.

FIG. 6 is a flowchart showing a configuration example of a manufacturing method of a rectenna according to an embodiment.

FIG. 7 is a cross-sectional view showing an example of a first state in a manufacturing method of a rectenna according to an embodiment.

FIG. 8A is a cross-sectional view showing an example of a second state in a manufacturing method of a rectenna according to an embodiment.

FIG. 8B is a cross-sectional view showing an example of another second state in a manufacturing method of a rectenna according to an embodiment.

FIG. 9 is a cross-sectional view showing an example of a third state in a manufacturing method of a rectenna according to an embodiment.

FIG. 10 is a cross-sectional view showing an example of a fourth state in a manufacturing method of a rectenna according to an embodiment.

FIG. 11 is a cross-sectional view showing an example of a fifth state in a manufacturing method of a rectenna according to an embodiment.

FIG. 12A is a cross-sectional view showing an example of a sixth state in a manufacturing method of a rectenna according to an embodiment.

FIG. 12B is another cross-sectional view showing an example of the sixth state in a manufacturing method of a rectenna according to an embodiment.

FIG. 13A is a cross-sectional view showing an example of a seventh state in a manufacturing method of a rectenna according to an embodiment.

FIG. 13B is another cross-sectional view showing an example of the seventh state in a manufacturing method of a rectenna according to an embodiment.

FIG. 14 is a flowchart showing a configuration example of a manufacturing method of a rectenna according to an embodiment.

FIG. 15A is a cross-sectional view showing a configuration example of a rectenna according to an embodiment.

FIG. 15B is another cross-sectional view of the rectenna shown in FIG. 15A.

FIG. 16 is a plan view showing a configuration example of a rectenna according to an embodiment.

### DETAILED DESCRIPTION

An embodiment for implementing a manufacturing method of a circuitry including a planar diode according to the present invention will be described below with reference to attached drawings.

To better understand each embodiment, two related arts will be described first. As a first related art, the rectenna of the above-mentioned Patent Literature 1 (Japanese Patent No. 5607676) will be described. As a second related art, the rectenna of the above-mentioned Non-Patent Literature 1 (Shun So, Department of Advanced Engineering Physics, 2017, University of Electro-communications, Master's thesis) will be described.

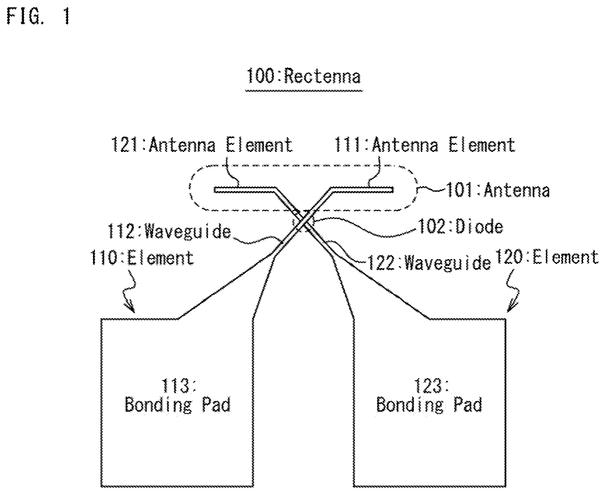

(First related art) With reference to FIG. 1, a configuration example of the rectenna 100 according to the first related art will be described. The rectenna 100 in FIG. 1 is provided with a first element 110 and a second element 120. The first element 110 is provided with a first antenna element 111, a first waveguide 112, and a first bonding pad 113. Similarly, the second element 120 is provided with a second antenna element 121, a second waveguide 122, and a second bonding pad 123. The first element 110 and the second element 120 are made of materials that are different from each other. Therefore, the two elements 110, 120 are formed on a same substrate in two different manufacturing processes, respectively. In case of FIG. 1, the second element 120 is formed at first, and then the first element 110 is formed. As a result, there is a portion where the first waveguide 112 overlaps the second waveguide 122. Furthermore, NiO (nickel oxide) is sandwiched between the first waveguide 112 and the second waveguide 122, and this overlapped portion functions as a laminated diode 102. Furthermore, the first antenna element 111 and the second antenna element 121 are arranged on a straight line, and function as an antenna 101 of the rectenna 100.

The antenna 101 of the rectenna 100 shown in FIG. 1 functions as a dipole antenna of which a feed section is connected to waveguides to which an anode and a cathode of the diode 102 are connected. Therefore, it is favorable that a length of the antenna 101 is approximatively half a wavelength of an electromagnetic wave that is desired to be received. In case the rectenna 100 converts infrared rays, visible rays, ultraviolet rays, and the like into electrical energy, it is favorable that the length of the antenna 101 is on an order of several hundred nanometers.

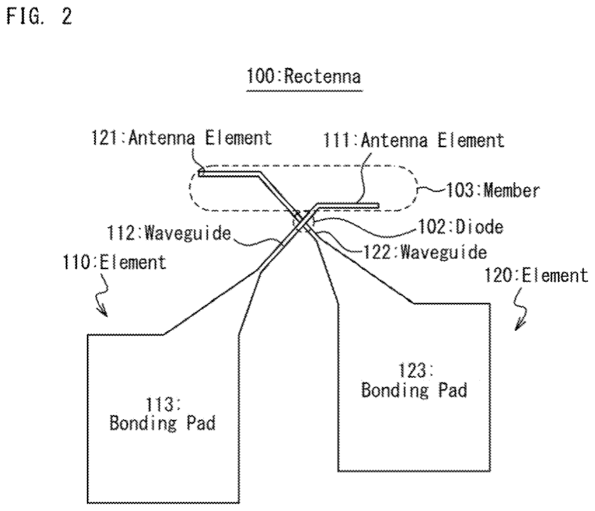

With reference to FIG. 2, a configuration example of the rectenna 100 according to the first related art in case where a manufacturing error has occurred will be described. Although the rectenna 100 in FIG. 2 is composed of the same elements as the rectenna 100 in FIG. 1, positional relationship between the first element 110 and the second element 120 is shifted, differently from the case in FIG. 1. As an end portion of the first antenna element 111 and an end portion of the second antenna element 121 are not arranged on a straight line, a member 103, that is composed of the end portion of the first antenna element 111 and the end portion of the second antenna element 121, does not function as an antenna.

As described above, an extremely high precision is required to a manufacturing process of overlapping the first element 110 and the second element 120 so that the rectenna 100 according to the first related art properly functions.

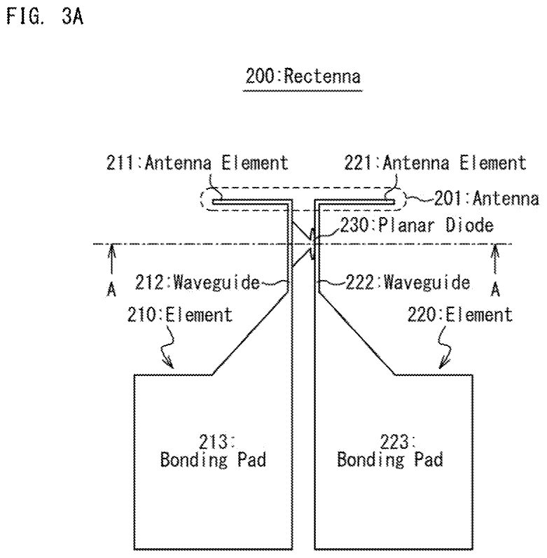

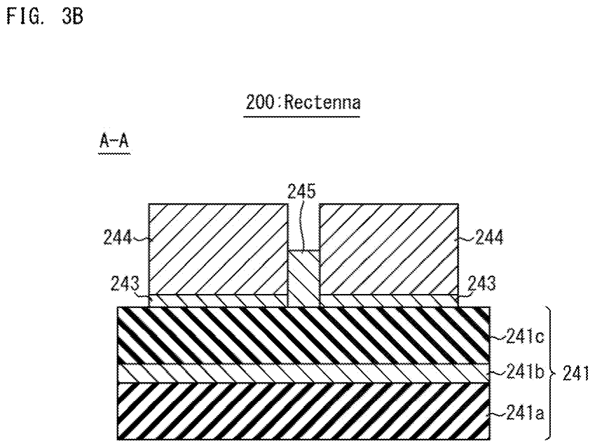

(Second related art) With reference to FIG. 3A and FIG. 3B, a configuration example of the rectenna 200 according to the second related art will be described. As shown in FIG. 3A, the rectenna 200 is provided with a first element 210, a second element 220, and a planar diode 230. The first element 210 is provided with a first antenna element 211, a first waveguide 212, and a first bonding pad 213. Similarly, the second element 220 is provided with a second antenna element 221, a second waveguide 222, and a second bonding pad 223. The first antenna element 211 and the second antenna element 221 function as an antenna 201 of the rectenna 200. The first element 210 and the second element 220 are made of a same material. Therefore, the two elements 210, 220 can be formed on a same substrate in a same manufacturing process at a same time.

The planar diode 230 is made of a nickel oxide layer that is a triangle-shaped nickel layer laminated on a substrate and then oxidized by irradiation with ultraviolet rays. When nickel is oxidized, the volume thereof increases. Herein, the nickel layer is laminated so that a side of the triangle is adjacent to the first waveguide 212 and a vertex of the triangle facing this side is adjacent to the second waveguide 222. Then, by oxidizing this nickel layer, the vertex portion deforms along the second waveguide 222. As a result, the nickel oxide layer has a shape that is appropriate to function as the planar diode 230. As an example, the planar diode 230 in FIG. 3A functions as a geometric diode.

In the example in FIG. 3B, a Ti (titan) layer 243 is laminated on the rectenna substrate 241, and an Au (gold) layer 244 is laminated thereon. The rectenna substrate 241 is provided with a substrate 241a made of Si (silicon) or the like, a reflective layer 241b that is Al (aluminum) or the like laminated thereon, and a dielectric layer 241c that is SiO₂ (silicon oxide) or the like laminated thereon by spattering method. The first element 210 is composed of the Ti layer 243 and the Au layer 244 that are shown in left side in FIG. 3B. The second element 220 is composed of the Ti layer 243 and the Au layer 244 that are shown in right side in FIG. 3B. NiO (nickel oxide) layer 245 is laminated on the dielectric layer 241c composed of SiO₂ or the like. The NiO layer 245 is adjacent to the first element 210 on one side and is adjacent to the second element 220 on the other side. The planar diode 230 is made of this NiO layer 245.

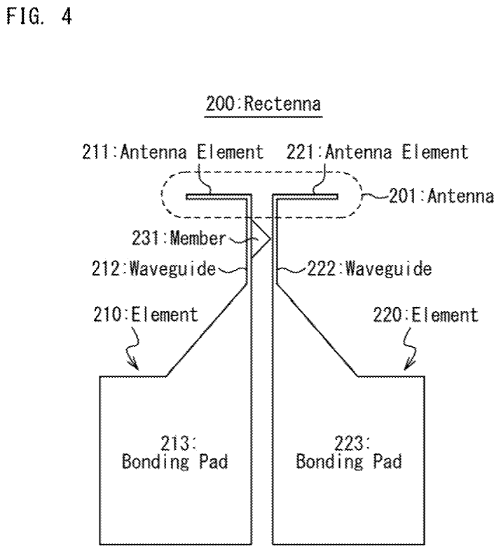

With reference to FIG. 4, a configuration example of the rectenna 200 according to the second related art in case where a manufacturing error has occurred will be described. In FIG. 4, although a member 231 composed of the NiO layer is adjacent to the first waveguide 212, the member 231 is not adjacent to the second waveguide 222. Furthermore, a vertex of the member 231 composed of the NiO layer does not reach the second waveguide 222; thus, the vertex has not deformed when the nickel has been oxidized and the planar diode 230 does not have the desired shape. As a result, the member 231 does not function as a planar diode of the rectenna 200.

As described above, in the second related art, since the two elements 210, 220 can be formed in a same manufacturing process, it is unlikely that the positional relationship between the first antenna element 211 and the second antenna element 221 is deviated to such an extent that the antenna 201 does not function. On the other hand, the manufacturing process of laminating the nickel layer on the substrate is performed as a process different from the manufacturing process of laminating the two elements 210, 220 on the substrate. Therefore, an extremely precision is required in an alignment between the two manufacturing processes.

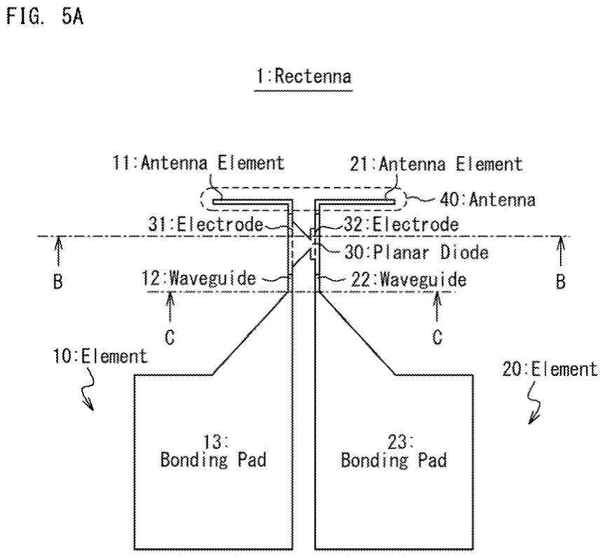

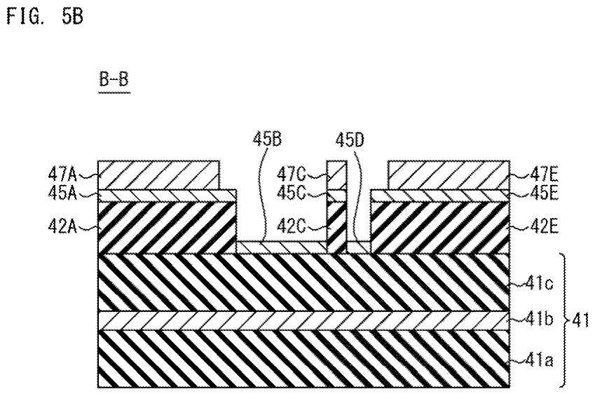

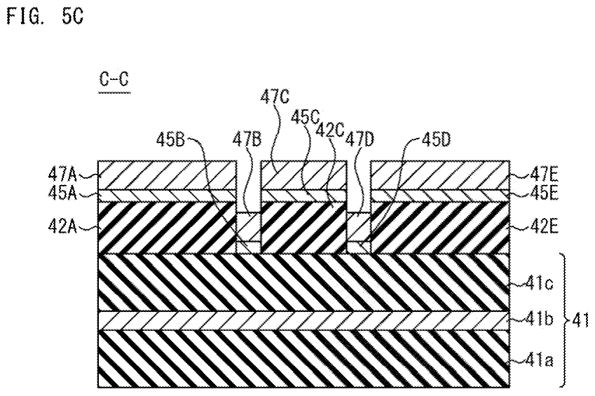

(First embodiment) With reference to FIG. 5A, FIG. 5B and FIG. 5C, a configuration example of a rectenna 1 according to an embodiment will be described. As shown in FIG. 5A, the rectenna 1 according to an embodiment is provided with a first element 10, a second element 20, and a planar diode 30. The first element 10 is provided with a first antenna element 11, a first waveguide 12, and a first bonding pad 13. The second element 20 is provided with a second antenna element 21, a second waveguide 22, and a second bonding pad 23.

One end portion of the first waveguide 12 is connected to the first antenna element 11. The other end portion of the first waveguide 12 is connected to the first bonding pad 13. Similarly, one end portion of the second waveguide 22 is connected to the second antenna element 21. The other end portion of the waveguide 22 is connected to the second bonding pad 23. An end portion of the first antenna element 11 opposite to the first waveguide 12 and an end portion of the second antenna element 21 opposite to the second waveguide 22 are arranged on a straight line. The first waveguide 12 and the second waveguide 22 are elongated to a same direction. In other words, the first waveguide 12 and the second waveguide 22 are arranged in parallel. The planar diode 30 has two electrodes 31, 32 with different polarities that function as an anode and a cathode, respectively. The first electrode 31 is connected to the first waveguide 12, and the second electrode 32 is connected to the second waveguide 22. The bonding pads 13, 23 are configured to be connected to an external device that receives electrical energy the rectenna 1 outputs.

The first antenna element 11 and the second antenna element 21 function as a dipole antenna 40 of which a feed section is connected to waveguides to which two electrodes 31, 32 of the planar diode 30 are connected, respectively. The planar diode 30 has both a configuration in which a width of a conductor through which a current can flow gradually narrows from the first electrode 31 to the second electrode 32, and a configuration in which, in contrary, the width of the conductor through which the current can flow sharply narrows from the second electrode 32 to the first electrode 31. With such configurations, the planar diode 30 according to an embodiment has characteristics of a geometric diode in that, electrons or holes can easily move in one direction of a first direction from the first electrode 31 to the second electrode 32 and a second direction from the second electrode 32 to the first electrode 31, and in contrary, have difficulty to move in the other direction. Herein, sizes of the planar diode 30 are appropriately determined based on the material of which the planar diode 30 is composed and an ease in a physical move of electrons through this material, so that the planar diode 30 functions as a diode having desired characteristics.

FIG. 5B is a cross-sectional view by a cross-sectional line B-B of the rectenna 1 shown in FIG. 5A. As shown in FIG. 5B, the planar diode 30 is composed of functional material layers 45B, 45D laminated on the substrate 41. In the example of FIG. 5B, the substrate 41 is configured similarly to the rectenna substrate 241 in FIG. 3B. In addition, the planar diode 30 is surrounded by insulating layers 42A, 42C, 42E in directions perpendicular to a lamination direction. For example, the insulation layers 42A, 42C, 42E are formed of a resist, a polymer film, or the like. The insulating layers 42A, 42C, 42E are also laminated by the functional material layers 45A, 45C, 45E thereon, respectively. In addition, the functional material layers 45A, 45C, 45E are laminated by the Au layers 47A, 47C, 47E thereon, respectively. As a thickness of the insulating layers 42A, 42C, 42E is larger than a thickness of the functional material layers 45B, 45D and there is a sufficient level difference in the lamination direction, the planar diode 30 is not short-circuited to the functional material layers 45A, 45C, 45E or the Au layers 47A, 47C, 47E that are surrounding.

In the following, when the insulating layers 42A, 42C, 42E and the like are not distinguished, they will be collectively referred to as an insulating layer 42. Similarly, when the functional material layers 45A, 45C, 45E and the like are not distinguished, they will be collectively referred to as a functional material layer 45. In addition, when Au layers 47A, 47C, 47E and the like are not distinguished, they will be referred to as an Au layer 47.

FIG. 5C is a cross-sectional view by a cross-sectional line C-C of the rectenna 1 shown in FIG. 5A. As shown in FIG. 5C, at least a part of the first waveguide 12 is provided with the functional material layer 45B laminated on the substrate 41 and the Au layer 47B laminated on the functional material layer 45B. Similarly, at least a part of the second waveguide 22 is provided with the functional material layer 45D laminated on the substrate 41 and the Au layer 47D laminated on the functional material layer 45D. It should be noted that each of the antenna elements 11, 21 and the bonding pads 13, 23 is provided with the functional material layer 45 and the Au layer 47 laminated on the functional material layer 45, similarly to the at least a part of the waveguides 12, 22. By laminating Au layer 47, resistance of the antenna elements 11, 21 and the bonding pads 13, 23 can be decreased compared to a case of composing the antenna elements 11, 21 and the bonding pads 13, 23 with only the functional material layer 45.

In addition, the waveguides 12, 22 are surrounded by the insulating layers 42A, 42C, 42E in directions perpendicular to the laminating direction. The insulating layers 42A, 42C, 42E are laminated by the functional material layers 45A, 45C, 45E thereon, respectively. In addition, the functional material layers 45A, 45C, 45E are laminated by the Au layers 47A, 47C, 47E thereon, respectively. As the thickness of the insulating layer 42 is larger than a sum of the thickness of the functional material layer 45 and the thickness of the Au layer 47, and there is a sufficient level difference in the laminating direction, the waveguides 12, 22 are not short-circuited to the functional material layers 45A, 45C, 45E or the Au layers 47A, 47C, 47E that are surrounding. At least a part of the antenna elements 11, 21 and the bonding pads 13, 23 may have a similar configuration as these waveguides 12, 22. However, as the antenna elements 11, 21 and the bonding pads 13, 23 are sufficiently separated from the planar diode 30, it is favorable to decrease resistance thereof by evaporating Au layer 47 on an entire surface thereof. As a part of the waveguides 12, 22 positioned in a proximity of the planar diode 30 is covered by a resist, there may be a region of the waveguides 12, 22 without Au layer 47.

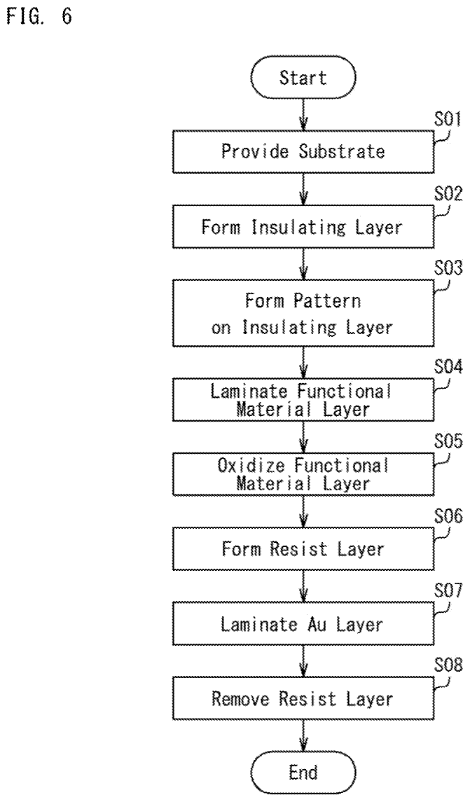

With reference to a flowchart in FIG. 6, a configuration example of a manufacturing method of a circuitry including the planar diode 30 according the present embodiment will be described. It should be noted that, although a case of manufacturing a rectenna 1 as an example of the circuitry including the planar diode 30 will be described herein, an embodiment is not limited to a manufacturing method of the rectenna 1 and is applicable to a manufacturing method of any circuitry including the planar diode 30 and a circuit element connected to the planar diode 30.

In a first step S01, the substrate 41 is provided. The substrate 41 may be formed like the rectenna substrate 241 shown in FIG. 3B. In case the substrate 41 is formed like the rectenna substrate 241, the substrate 41 is provided with a substrate 41a, a conductive layer 41b laminated thereon, and a dielectric layer 41c further laminated thereon. The substrate 41a is, for example, composed of Si (silicon). The conductive layer 41b is, for example, formed by laminating a conductor such as Al (aluminum) on the substrate 41a and functions as a reflective plate. The dielectric layer 41c is, for example, formed by laminating a dielectric such as SiO₂ (silicon oxide) on the conductive layer 41b by spattering method or the like. A thickness of the dielectric layer 41c is determined based on a permittivity of the dielectric and a wavelength of electromagnetic waves desired to be reflected by the conductive layer 41b so that incident waves, that are electromagnetic waves incident from a surface of the dielectric layer 41c, and reflected waves, that are the incident waves reflected by the conductive layer 41b and reaching the surface of the dielectric layer 41c, strengthen each other. Although it will be described later in detail, in other words, the thickness of the dielectric layer 41c is adjusted so that an efficiency of the antenna 40 formed on the dielectric layer 41c becomes maximal. The configuration of the substrate 41 described above is merely an example and does not limit an embodiment.

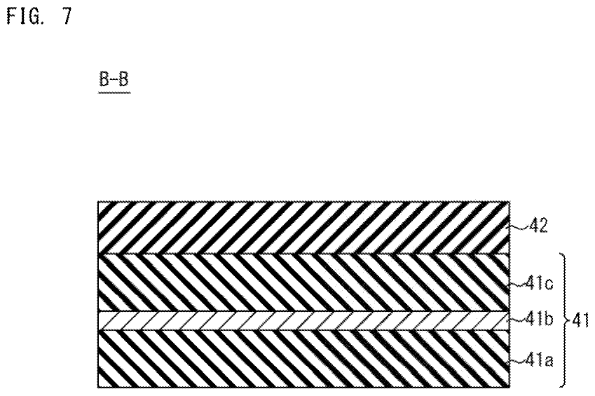

In a step S02, the insulating layer 42 is formed on the substrate 41. The insulating layer 42 is, for example, made of an insulator such as a resist or a polymer that facilitates a formation of a desired pattern in a next step S03. The above-described configuration of the insulating layer 42 is merely an example and does not limit an embodiment. By doing so, a state shown in FIG. 7 is obtained. Although FIG. 7 is a cross-sectional view by the cross-sectional line B-B shown in FIG. 5A, in fact, any location other than the cross-sectional line B-B is similarly configured at the time of the step S02.

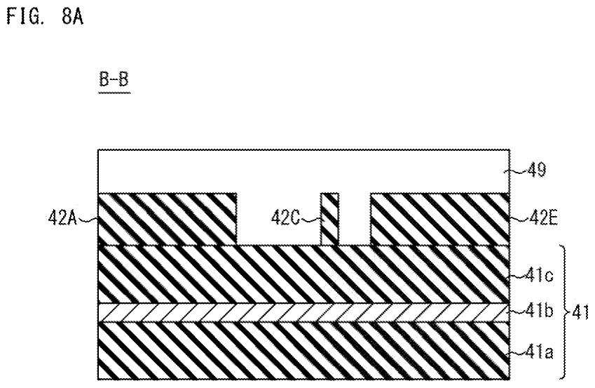

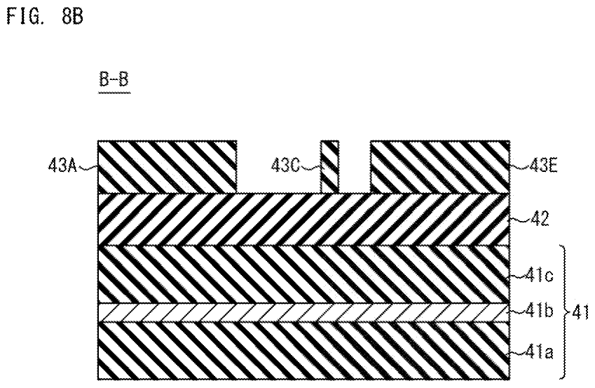

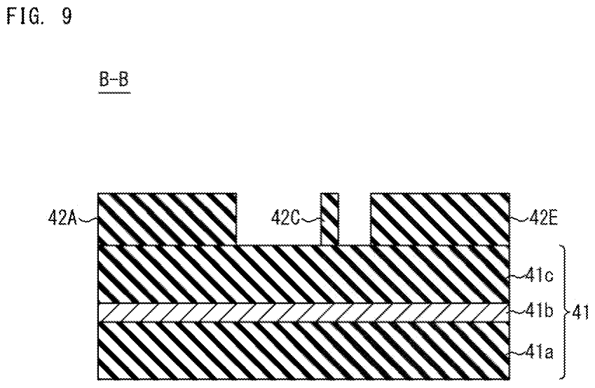

In a step S03, a desired pattern is formed on the insulating layer 42. Herein, three methods to form a pattern on the insulating layer 42 will be described with reference to FIG. 8A, FIG. 8B, and FIG. 9.

In a first method of the third step S03, a nanoimprint mold 49 having a desired circuit pattern shape is pushed against the insulating layer 42. This circuit pattern shape has a shape of a circuitry including the planar diode 30, and specifically, has a shape of a circuitry including the planar diode 30 and a circuit element connected to the electrodes 31, 32 of this planar diode 30. In an embodiment, this circuit pattern shape has a shape of the rectenna 1 that is shown in FIG. 5A and has the planar diode 30, the first element 10, and the second element 20. By doing so, a state shown in FIG. 8A is obtained. FIG. 8A is a cross-sectional view by the cross-sectional line B-B shown in FIG. 5A.

Of the insulating layer 42, a first portion having this circuit pattern shape is removed, and a second portion having a complementary pattern shape that is complementary to this circuit pattern shape remains as the insulating layers 42A, 42C, 42E shown in FIG. 8A. When the insulating layer 42 is not completely removed from a recess having the circuit pattern shape after the nanoimprint mold 49 is removed, a remaining part of the insulating layer 42 may be removed from this recess by a dry etching method or the like. As at that time a portion of the surface of the insulating layers 42A, 42C, 42E having the complementary pattern shape is also removed, a corresponding portion of thickness may be added in advance when forming the insulating layer 42 at the second step S02. By doing so, a state shown in FIG. 9 is obtained. FIG. 9 is a cross-sectional view by the cross-sectional line B-B shown in FIG. 5A. This first method can be applied even if the insulating layer 42 is a resist or a polymer film appropriated to nanoimprinting.

The second method of the third step S03 is lithography and can be applied when the insulating layer 42 is made of a material except a resist, for example a polymer or the like. At first, a resist layers 43A, 43C, 43E having a complementary pattern shape that is complementary to a desired circuit pattern shape is formed on the insulating layer 42. By doing so, a state shown in FIG. 8B is obtained. FIG. 8B is a cross-sectional view by the cross-sectional line B-B shown in FIG. 5A. In the following, when the resist layers 43A, 43C, 43E are not distinguished, they will be collectively referred to as a resist layer 43.

Next, a portion of the insulating layer 42 that is not covered by the resist layer 43 is removed by etching method, and then the resist layer 43 is removed. By doing so, a state shown in FIG. 9 is obtained.

The third method of the third step S03 can be applied for example when the insulating layer 42 is a resist. A complementary pattern shape that is complementary to the circuit pattern shape is formed on the insulating layer 42 that is a resist by lithography method. By doing so, the state shown in FIG. 9 is obtained.

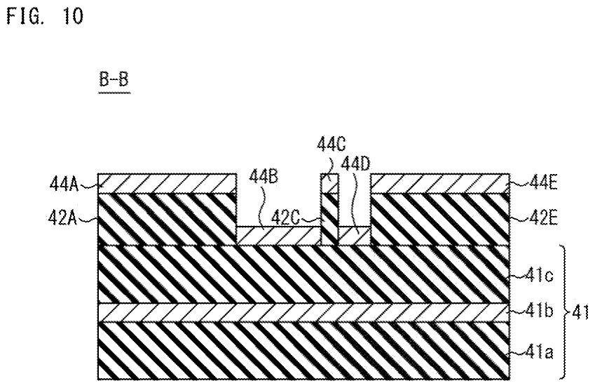

In a fourth step S04, the functional material layers 44A, 44B, 44C, 44D, 44E are laminated. When the functional material layers 44A, 44B, 44C, 44D, 44E are not distinguished, they will be collectively referred to as a functional material layer 44. In an embodiment, the functional material layer 44 is made of Ni (Nickel). As it will be described in the following, a material having characteristics of functioning as the planar diode 30 will be referred to as functional material for sake of convenience. In addition, a material that can acquire similar characteristics by addition of a process such as oxidizing by a given method will be also referred to as functional material for sake of convenience. Of the functional material layer 44, the functional material layers 44A, 44C, 44E are laminated on the insulating layers 42A, 42C, 42E, respectively. Of the functional material layer 44, the functional material layers 44B, 44D are laminated on portions of the substrate 41 of which a surface is exposed due to removal of the insulating layer 42 for example. By doing so, a state shown in FIG. 10 is obtained.

In a fifth step S05, the functional material layer 44 is oxidized. By oxidizing Ni of the functional material layer 44, a functional material layer 45 made of NiO (nickel oxide) having characteristics of P-type semiconductor is obtained. Each of the functional material layers 44A, 44B, 44C, 44D, 44E of Ni is oxidized to become functional material layers 45A, 45B, 45C, 45D, 45E of NiO. When the functional material layers 45A, 45B, 45C, 45D, 45E are not distinguished, they will be collectively referred to as a functional material layer 45.

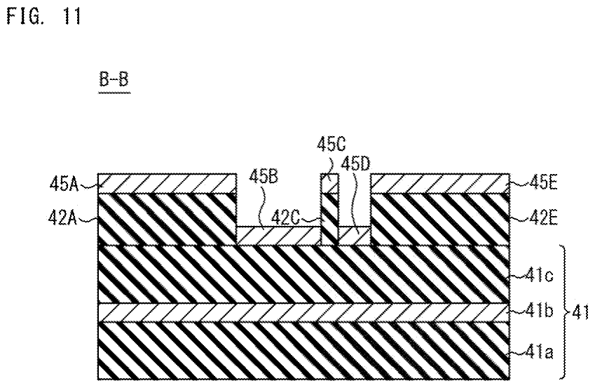

As a specific example of a method of oxidizing Ni, Ni of the functional material layer 44 may be oxidized into NiO of the functional material layer 45 by irradiating with ultraviolet rays in a relatively low temperature equal to or less than 500° C., as described in the Non-Patent Literature 1. At that time, according to the Non-Patent Literature 1, as a result of deformation due to oxidation of a vertex portion in the triangle shape of the functional material layer 44 of Ni that is in contact with the waveguide, a shape appropriate to one electrode 32 of the planar diode 30 is obtained. In the present embodiment, the shape of the planar diode 30 may be realized by a self-formation as a result of a similar deformation due to oxidation. As another example, in the present embodiment, a deformation of the functional material layer 44 of Ni in planar directions perpendicular to the lamination direction due to the oxidation may be suppressed by forming the functional material layer 44 of Ni in a desired shape of the planar diode 30 and surrounding the functional material layer 44 with the insulating layer 42. By doing so, a state shown in FIG. 11 is obtained.

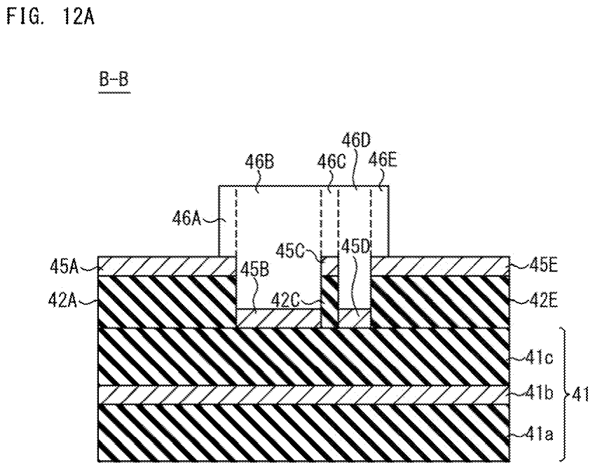

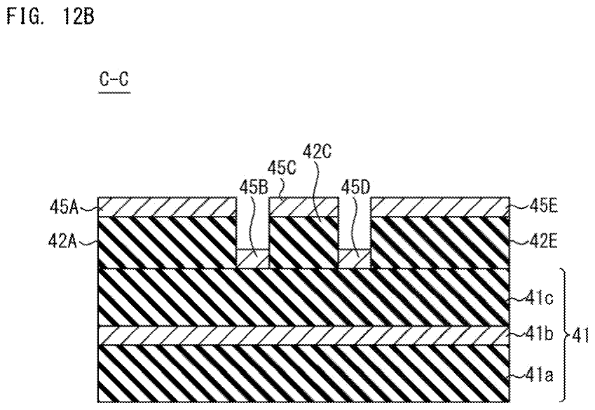

In a sixth step S06, resist layers 46A, 46B, 46C, 46D, 46E are formed. Although regions and names of the resist layers 46A, 46B, 46C, 46D, 46E are distinguished in order to make description easier, they actually are integrated. When the resist layers 46A, 46B, 46C, 46D, 46E are not distinguished, they will be collectively referred to as a resist layer 46. The resist layers 46B, 46D are selectively laminated on portions of the functional material layer 45 that are to be included in the planar diode 30. In accordance with a precision of the lithography method, the resist layers 46A, 46C, 46E may be selectively laminated also on portions around the portions to function as the planar diode 30. In an embodiment, the resist layers 46A, 46E are selectively laminated on portions of the functional material layer 45 that are included in the waveguides 12, 22 and are to be joined to the electrodes 31, 32 of the planar diode 30. In other words, it is important to securely cover the portion of the functional material layer 45 that is to function as the planar diode 30 with the resist layer 46. On the other hand, the resist layer 46 is not laminated on at least a portion of the functional material layer 45 to be included in the antenna elements 11, 21 and a portion of the functional material layer 45 to be included in the bonding pads 13, 23. By doing so, a state shown in FIG. 12A and FIG. 12B is obtained. Herein, FIG. 12A is a cross-sectional view at a same position as the cross-sectional line B-B shown in FIG. 5A, and FIG. 12B is a cross-sectional view at a same position as the cross-sectional line C-C shown in FIG. 5A.

It should be noted that, although a surface of the resist layer 46 is illustrated in FIG. 12A such to be flush, the surface of the resist layer 46 may have a shape other than flush in accordance with parameters such as a viscosity of the resist in the resist layer 46 and sizes of each of the resist layers 46A, 46B, 46C, 46D, 46E.

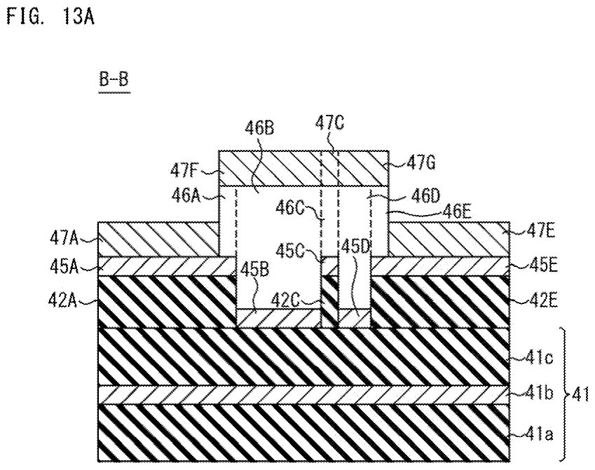

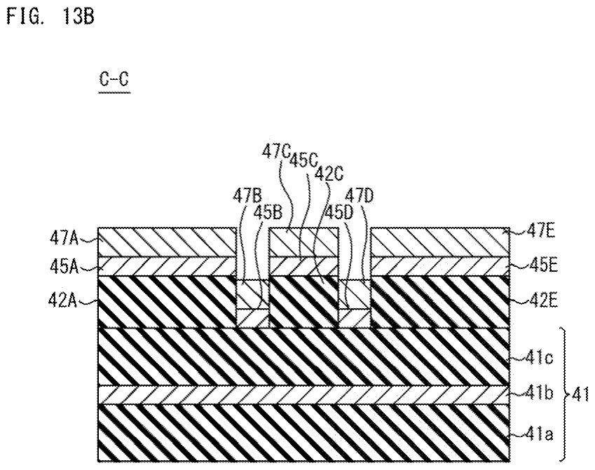

In a seventh step S07, the Au layer 47 is laminated. In more detail: the Au layer 47F is laminated on the resist layers 46A, 46B; the Au layer 47C is laminated on the resist layer 46C; and the Au layer 47G is laminated on the resist layers 46D, 46E. Herein, although regions and names of the Au layers 47C, 47F, 47G are distinguished for sake of convenience, they may actually be integrally formed. In addition, the Au layer 47A is laminated on a portion of the functional material layer 45A on which the resist layer 46A is not laminated, and the Au layer 47E is laminated on a portion of the functional material layer 45E on which the resist layer 46E is not laminated. By doing so, a state shown in FIG. 13A and FIG. 13B is obtained. FIG. 13A is a cross-sectional view at a same position as the cross-sectional line B-B shown in FIG. 5A, and FIG. 13B is a cross-sectional view at a same position as the cross-sectional line C-C shown in FIG. 5A.

Herein, a thickness of the resist layer 46 is set such that a first portion of the Au layer 47 including Au layers 47A, 47E and a second portion of the Au layer 47 including Au layers 47C, 47F, 47G are separated.

In an eighth step S08, the resist layer 46 is removed. At that time, the Au layers 47C, 47F, 47G that were laminated on the resist layer 46 are lifted off. By doing so, the rectenna 1 in the state shown in FIG. 5A, FIG. 5B and FIG. 5C is obtained. When the eighth step S08 ends, the flowchart in FIG. 6 ends.

As described above, the rectenna 1 according to the present embodiment is manufactured and configured so that the functional material layer 45 that is monolithically formed, that is, formed on one substrate 41, is included in the first element 10, the second element 20, and the planar diode 30 that are included in the rectenna 1. As a result, no misalignment occurs between the first antenna element 11 and the second antenna element 21 based on an error in two manufacturing processes as in the Patent Literature 1. In addition, no misalignment occurs between the two waveguides 12, 22 and the planar diode 30 based on an error in the two manufacturing processes as in the Non-Patent Literature 1. In other words, according to the present embodiment, the precision of positional relationship between the two elements 10, 20 and the planar diode 30 with which the rectenna 1 is provided can be improved.

(Second embodiment) In the present embodiment, as a variation example of the above-described first embodiment, the functional material layer 45 and the Au layer 47 that are around the rectenna 1 are removed. By doing so, in the present embodiment, a limitation in directions from which external light reaches the antenna elements 11, 21 is suppressed. In other words, as more light reaches the antenna elements 11, 21, an antenna efficiency in the rectenna 1 is improved. Therefore, according to the present embodiment, an efficiency of conversion from light to current by the rectenna 1 is further improved.

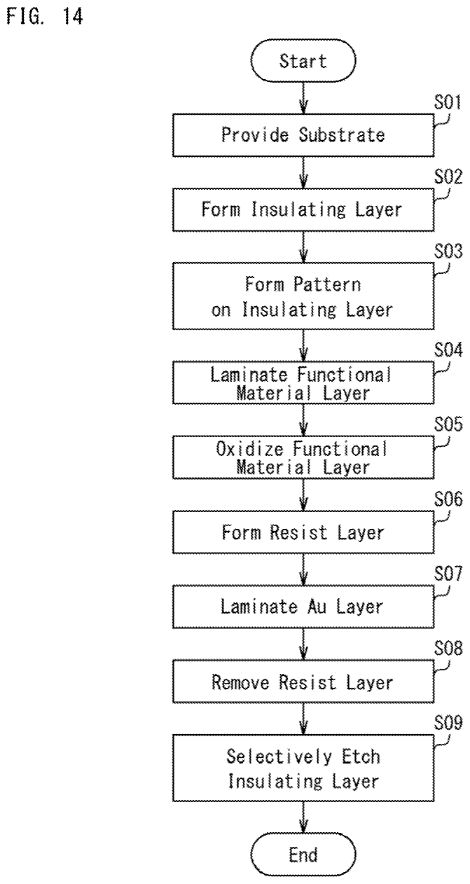

With reference to a flowchart in FIG. 14, a configuration example of the manufacturing method of the circuitry including the planar diode 30 according to the present embodiment will be described.

The flowchart in FIG. 14 is equivalent to the flowchart in FIG. 6 added with following modification. That is, a ninth step S09 is executed after the eighth step S08 and then the flowchart ends.

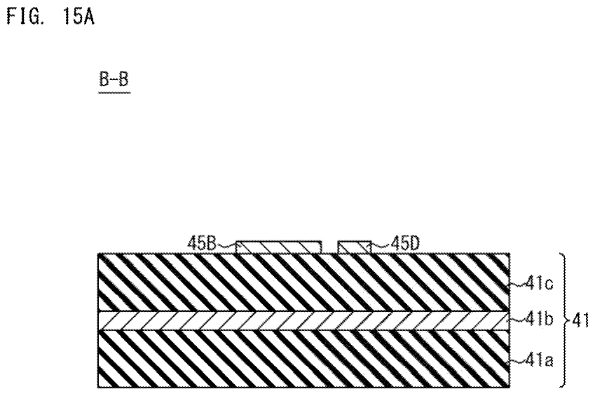

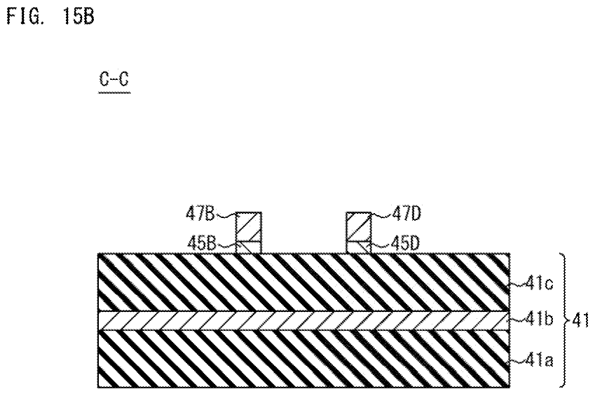

In the ninth step S09, the insulating layer 42 is selectively etched. As a result, the insulating layer 42 is removed. In addition, of the functional material layer 45 and the Au layer 47, a portion laminated on the substrate 41 remains and a portion laminated on the insulating layer 42 is lifted off. By doing so, the rectenna 1 in a state shown in FIG. 15A and FIG. 15B is obtained.

The rectenna 1 manufactured by the manufacturing method of the circuitry including the planar diode 30 according to the present embodiment is equivalent to the rectenna 1 according to the first embodiment shown in FIG. 5A added with following modifications. That is, the insulating layer 42, the functional material layer 45, and the Au layer 47 that are around the rectenna 1 are removed. In the rectenna 1 according to the present embodiment also, similarly to the case of the first embodiment, no misalignment occurs between the first antenna element 11 and the second antenna element 21 based on an error in the two manufacturing processes as in the Patent Literature 1. In addition, no misalignment occurs between the two waveguides 12, 22 and the planar diode 30 based on an error in the two manufacturing processes as in the Non-Patent Literature 1. In other words, according to the present embodiment, a precision of positional relationship between the two elements 10, 20 and the planar diode 30 with which the rectenna 1 is provided can be improved.

As described above, according to each of the above-described embodiments, of the circuitry including the planar diode 30, the planar diode 30 and the circuit element connected to the planar diode 30 are formed on one substrate 41, that is, monolithically formed. Therefore, a manufacturing precision of connections between the planar diode 30 and the circuit element connected to the planar diode 30 can be improved. Each of the above-described embodiments can be applied to a manufacturing of a microscopic circuitry in which it is difficult to connect by soldering the planar diode 30 and the circuit element to be connected to the planar diode 30 after manufacturing them in different processes.

Although the invention made by the inventors has been described above in detail based on embodiments, it is needless to declare that the present invention is not limited to the embodiments and various modifications can be made without departing from a gist thereof. In addition, each of the characteristics described in the embodiments can be freely combined within a technically consistent range.

As a variation example of each embodiment, the substrate 41a of the substrate 41 formed like the rectenna substrate 241 may be made of a material other than Si. In addition, the substrate 41 may be a substrate having a configuration different from the rectenna substrate 241.

As a variation example of each embodiment, the Au layer 47 may be substituted to a metallic layer in which a metal other than gold is laminated, may be substituted to a plurality of metallic layers in which gold and another metal are laminated, and may be substituted to a metallic layer in which an alloy of gold and another metal is laminated. In any case, by laminating a metallic layer on the functional material layer 45, a conductivity of a part or all of the antenna elements 11, 21, the waveguides 12, 22, and the bonding pads 13, 23 can be improved.

As a variation example of the first embodiment and the second embodiment, the material of which the planar diode 30 is formed may be substituted to a material other than NiO. As an example, the planar diode 30 may be formed by substituting NiO to graphene, and the planar diode 30 may be formed with ZnO (zinc oxide) that is obtained by oxidizing Zn (zinc) substituted for Ni. These materials that function as the planar diode 30 having rectifying properties by having a predetermined shape and being connected to predetermined circuit element will be referred to as functional materials for sake of convenience. In other words, functional materials are materials having rectifying properties based on their shapes and their sizes, or materials prior to oxidation thereof. When using a functional material such as graphene that does not need an oxidation process to function as the planar diode 30, the fifth step S05 in the flowcharts in FIG. 6 and FIG. 14 may be omitted. In any case, it is favorable to monolithically form on one substrate 41 at least the planar diode 30 and a circuit element to be connected to the planar diode 30.

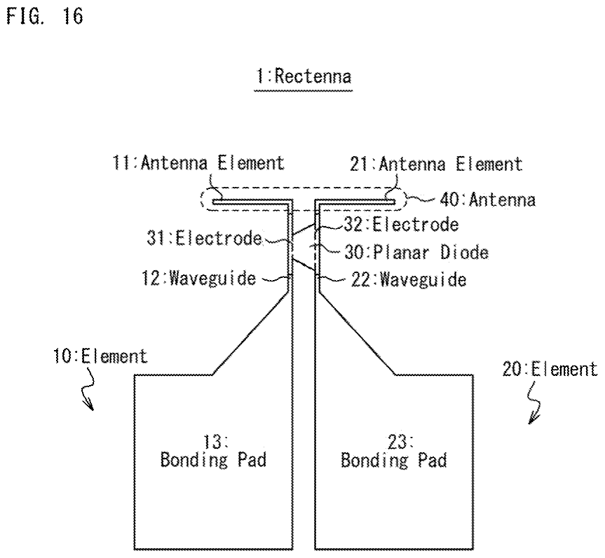

As a variation example of the first embodiment and the second embodiment, as shown in FIG. 16, the planar diode 30 may be configured to function as a fully depleted Schottky diode of which contact areas on both ends are different. In a fully depleted Schottky diode, the depletion layer width extends across the diode. Herein, when a contact area between a first end of the planar diode 30 and a metallic portion of the first waveguide is made smaller than a predetermined area, this contact part has characteristics of a Schottky contact. An electrode having a Schottky contact is referred to as a Schottky electrode. In addition, when a contact area between a second end of the planar diode 30 as the second electrode 32 thereof and a metallic portion of the second waveguide is made larger than a predetermined area, this contact part has characteristics of an ohmic contact. An electrode having an ohmic contact is referred to as an ohmic electrode. In this case, when the contact part at the first end is positively biased compared to the contact part at the second end, electrons are tunneled through the diode from the contact part at the second end to the contact part at the first end. Therefore, in the forward direction, the current flows from the first end to the second end. Herein, the first end corresponds to the first electrode 31 of the planar diode 30, and the second end corresponds to the second electrode 32 of the planar diode 30.

It should be noted that the above-described fully depleted Schottky diode is different from a common Schottky diode in following points. That is, in a common Schottky diode, as holes at P-type semiconductor side flow from the semiconductor to the Schottky electrode, a forward direction current flows when the ohmic electrode of the P-type semiconductor is positively biased with respect to the Schottky electrode. On the other hand, in a fully depleted Schottky diode, as depletion layer extends across the semiconductor and there is no hole in the semiconductor, when ohmic electrode of the semiconductor is negatively biased with respect to the Schottky electrode, electrons tunnel the depletion layer of the semiconductor from the metal in ohmic contact with the semiconductor and flow to the Schottky electrode. That is, in a fully depleted Schottky diode, the forward direction is opposite to that of a common Schottky diode.

In a Schottky electrode, in order to make NiO as the P-type semiconductor of the planar diode 30 and Au as the metal of the first waveguide in contact, an appropriate modification may be added to the manufacturing process. For example, a groove may be provided along the first waveguide for Au to exist between the planar diode 30 and the first waveguide, a shape of a mask used to evaporate Au may be appropriately modified, and a height of the planar diode 30 may be made higher than the first waveguide.

The present application claims a priority based on Japanese Patent Application No. 2021-38902, filed on Mar. 11, 2021, the entire disclosure thereof is incorporated herein by reference.

1. A manufacturing method of a circuitry including a planar diode, the method including:
forming an insulating layer having a first pattern shape on a substrate; and
monolithically forming a functional material layer having a second pattern shape complementary to the first pattern shape on the substrate,
wherein the functional material layer includes a material configured to function as a planar diode having a rectifying property based on a shape and a size, and
wherein the second pattern shape has a shape of a circuitry including the planar diode, a first circuit element connected to a first electrode of the planar diode, and a second circuit element connected to a second electrode of the planar diode.

2. The manufacturing method of the circuitry including the planar diode according to claim 1, the method further including:
laminating a metallic layer at a single process on a first part of the functional material layer except at least a second part of the functional material layer that functions as the planar diode.

3. The manufacturing method of the circuitry including the planar diode according to claim 2, wherein a thickness of the insulating layer is larger than a sum of a thickness of the functional material layer and a thickness of the metallic layer.

4. The manufacturing method of the circuitry including the planar diode according to claim 3, the method further including:
removing the insulating layer by selectively etching.

5. The manufacturing method of the circuitry including the planar diode according to claim 4,
wherein the forming the functional material layer includes forming, on the insulating layer, another functional material layer separated from the functional material layer formed on the substrate,
wherein the laminating the metallic layer on the second part of the functional material layer includes laminating, on the another functional material layer, another metallic layer separated from the metallic layer, and
wherein the selectively etching includes selectively lifting off the another functional material layer and the another metallic layer.

6. The manufacturing method of the circuitry including the planar diode according to claim 1, wherein the planar diode comprises a geometric diode.

7. The manufacturing method of the circuitry including the planar diode according to claim 1,
wherein the forming the insulating layer includes:
forming the insulating layer that is integral on the substrate;
pushing a nanoimprint mold against the insulating layer to form the first pattern shape on the insulating layer; and
adjusting the first pattern shape of the insulating layer by dry-etching.

8. The manufacturing method of the circuitry including the planar diode according to claim 1, wherein the forming the insulating layer includes forming the insulating layer with a polymer.

9. The manufacturing method of the circuitry including the planar diode according to claim 1, wherein the forming the insulating layer includes forming the insulating layer with a resist.

10. The manufacturing method of the circuitry including the planar diode according to claim 1,
wherein the forming the functional material layer includes:
laminating a nickel layer having the first pattern shape on the substrate; and
oxidizing the nickel layer by irradiating with ultraviolet ray at a temperature equal to or lower than 500° C.

11. The manufacturing method of the circuitry including the planar diode according to claim 1,
wherein the forming the functional material layer includes:
laminating a nickel layer on the substrate;
oxidizing the nickel layer by irradiating with ultraviolet ray at a temperature equal to or lower than 500° C.; and
realizing a self-forming of a shape of the planar diode included in the first pattern shape by a deformation of the nickel layer due to oxidation.

12. The manufacturing method of the circuitry including the planar diode according to claim 1, wherein the circuitry including the shape of the second pattern shape further includes an antenna with a feed section connected to the first circuit element and the second circuit element.
